(19) United States
(12) Patent Application Publication
(10) Pub. No.: US 2008/0079047 A1
(43) Pub. Date: Apr. 3, 2008

(54) Memory device and method of reading/writing data from/into a memory device

(76) Inventor: Joerg Dietrich Schmid, Dresden (DE)

Correspondence Address: SLATER & MATSIL LLP, 17950 PRESTON ROAD, SUITE 1000, DALLAS, TX, 75252, US

(21) Appl. No.: 11/541,630

(22) Filed: Sep. 29, 2006

(51) Int. Cl. H01L 29/94

(52) U.S. Cl. 257/296

(57) ABSTRACT

In an embodiment of the invention a memory device is provided including a plurality of memory cells, each of which comprises a first electrode, a second electrode and an active material arranged between the first electrode and the second electrode, the first electrodes being arranged parallel to each other and which are isolated against each other, and the memory cells being grouped into memory cell groups, each memory cell group defining a memory cell group area and being configured such that corresponding first electrodes are individually addressable via the first electrodes, and corresponding second electrodes are commonly addressable via a common select device arranged within the memory cell group area of the memory cell group.

### TECHNICAL FIELD

The invention relates to a memory device, a method of reading data stored within a memory device, and a method of writing data into a memory device.

### BACKGROUND

It is desirable to increase the memory density of memory devices.

### SUMMARY OF THE INVENTION

According to one embodiment of the present invention, a memory device including a plurality of memory cells, each of which includes a first electrode, a second electrode and an active material arranged between the first electrode and the second electrode. The first electrode is patterned into regions, e.g., parts of stripe-shaped electrodes, e.g., parallel stripes, which are arranged parallel to each other and which are isolated against each other. The memory cells are grouped into memory cell groups, each memory cell group defining a memory cell group area and being configured such that corresponding first electrodes are individually addressable via the stripe-shaped electrodes, and corresponding second electrodes are commonly addressable via a common select device arranged within the memory cell group area of the memory cell group.

### BRIEF DESCRIPTION OF THE DRAWINGS

For a more complete understanding of exemplary embodiments of the present invention and the advantages thereof, reference is no made to the following description taken in conjunction with the accompanying drawings, in which:

FIG. 1a shows a schematic cross-sectional view of a solid electrolyte random access memory cell set to a first memory state;

FIG. 1b shows a schematic cross-sectional view of a solid electrolyte random access memory cell set to a second memory state;

FIG. 2 shows a schematic cross-sectional view of a part of one embodiment of a memory device;

FIG. 3 shows a schematic top view of a part of one embodiment of the memory device according to the present invention;

FIG. 4 shows a schematic cross-sectional view of a part of one embodiment of a memory device according to the present invention;

FIG. 5 shows a schematic top view of a part of one embodiment of a memory device;

FIG. 6 shows a flow chart of one embodiment of the method of reading data from a memory cell according to the present invention;

FIG. 7 shows a flow chart of one embodiment of the method of writing data into a memory cell according to the present invention; and

FIG. 8 shows a schematic cross-sectional view of a part of another embodiment of a memory device according to the present invention.

### DETAILED DESCRIPTION OF ILLUSTRATIVE EMBODIMENTS

According to one embodiment of the present invention, a memory device including a plurality of memory cells, each of which includes a first electrode, a second electrode and an active material arranged between the first electrode and the second electrode. The first electrodes are parts of stripe-shaped electrodes, which are arranged parallel to each other and which are isolated against each other. The memory cells are grouped into memory cell groups, each memory cell group defining a memory cell group area and being configured such that corresponding first electrodes are individually addressable via the stripe-shaped electrodes, and corresponding second electrodes are commonly addressable via a common select device arranged within the memory cell group area of the memory cell group.

The term “memory cell area” means the region of the memory device that is occupied by the memory cells assigned to the memory cell area and/or the region of the memory device above and under this region.

According to one embodiment of the present invention, the stripe-shaped electrodes are address lines. According to this embodiment, the first electrodes of the memory cells of a memory cell group are electrically connected to (to be more precise, the memory cells of a memory cell group are a part of) an “own” address line, respectively, i.e., the address line being electrically connected to the first electrode of a particular memory cell is not electrically connected to other first electrodes of memory cells belonging to the same memory cell group. However, the address line may contact further first electrodes belonging to memory cells of other memory cell groups. In this way, it is ensured that each memory cell of the memory device can be uniquely addressed although the second electrodes of a memory cell group are simultaneously addressed via a corresponding common select device assigned to the memory cell group. If the memory cell groups overlap with each other, i.e., if memory cells assigned to a particular memory cell group are also assigned to further memory cell groups, several ways exist to uniquely address a particular memory cell.

One advantage of this embodiment is that, in order to increase the memory depth of the memory device, the spatial dimensions of the select devices of the memory device do not have to be scaled down. Since each common select device is shared by several memory cells, more space is available for each common select device (compared to select devices of memory devices in which each select device is coupled to only one memory cell).

According to one embodiment of the present invention, the stripe-shaped electrodes are generated by patterning a continuous common electrode covering the active material.

According to one embodiment of the present invention, the memory cells form a memory cell array including memory cell rows and memory cell columns, wherein the stripe-shaped electrodes are arranged parallel to the memory cell rows.

According to one embodiment of the present invention, each memory cell group includes two memory cells, wherein each stripe-shaped electrode is electrically connected to only one memory cell of a memory cell group, i.e., contacts only one first electrode assigned to a memory cell group.

According to one embodiment of the present invention, the pitch of the stripe-patterned electrodes is substantially the same as that of the second electrodes. This means that the same lithography tools can be used for both patterning the stripe-shaped electrodes and the second electrodes.

According to one embodiment of the present invention, the common select devices form a select device array including select device rows and select device columns, wherein the select devices of a select device column are simultaneously addressable.

According to one embodiment of the present invention, each stripe-shaped electrode is arranged perpendicular to a column of common select devices simultaneously addressable.

According to one embodiment of the present invention, all memory cell groups have the same memory cell group architecture.

According to one embodiment of the present invention, the memory cells have a vertical architecture, respectively (i.e., a connection line between the first electrode and the second electrode of a memory cell extends substantially in a vertical direction).

According to one embodiment of the present invention, the memory cells have a lateral architecture, respectively (i.e., a connection line between the first electrode and the second electrode of a memory cell extends substantially in a lateral direction).

Generally, the number of second electrodes of each memory cell group can be chosen arbitrarily. For example, according to one embodiment of the present invention, each memory cell group is configured such that the corresponding memory cells of the memory cell group include only one common second electrode.

According to one embodiment of the present invention, each memory cell group is configured such that corresponding first electrodes are arranged around a common second electrode.

According to one embodiment of the present invention, each memory cell group is configured such that corresponding first electrodes are arranged around a common second electrode in a point-symmetrical manner.

According to one embodiment of the present invention, the memory device is a non-volatile memory device and/or a resistive memory device.

According to one embodiment of the present invention, the memory device is a solid electrolyte random access memory device, wherein the active material is solid electrolyte material.

According to one embodiment of the present invention, the memory device is a solid electrolyte random access memory device (CBRAM), wherein the active material is solid electrolyte material. According to one embodiment of the present invention, the memory device is a phase changing random access memory device (PCRAM), wherein the active material is phase changing material. The present invention is not restricted to these embodiments.

According to one embodiment of the present invention, a DRAM device is provided including a plurality of memory cells, each of which includes a first electrode, a second electrode and a dielectric material arranged between the first electrode and the second electrode. The first electrodes are parts of stripe-shaped electrodes, which are arranged parallel to each other and which are isolated against each other. The memory cells are grouped into memory cell groups, each memory cell group defining a memory cell group area and being configured such that corresponding first electrodes are individually addressable via the stripe-shaped electrodes, and corresponding second electrodes are commonly addressable via a common select device arranged within the memory cell group area of the memory cell group.

All embodiments of the memory device according to the present invention discussed above may also be applied to the embodiment of the DRAM device according to the present invention.

According to one embodiment of the present invention, the first electrodes are top electrodes, and the second electrodes are bottom electrodes (vertical memory cell architecture).

According to one embodiment of the present invention, a method of reading data stored within a memory device is provided. The memory device includes a plurality of memory cells, each of which has a first electrode, a second electrode and an active material arranged between the first electrode and the second electrode. The first electrodes are parts of stripe-shaped electrodes, which are arranged parallel to each other and which are isolated against each other. The memory cells are grouped into memory cell groups, each memory cell group defining a memory cell group area and being configured such that corresponding first electrodes are individually addressable via the stripe-shaped electrodes, and corresponding second electrodes are commonly addressable via a common select device arranged within the memory cell group area of the memory cell group. The method includes selecting a memory cell from which data has to be read, selecting a memory cell group including the selected memory cell, and reading the data stored within the memory cell by applying a sensing signal to the selected memory cell via the stripe-shaped electrode assigned to the selected memory cell and the selecting device assigned to the selected memory cell group.

According to one embodiment of the present invention, a method of writing data into memory device is provided. The memory device includes a plurality of memory cells, each of which has a first electrode, a second electrode and an active material arranged between the first electrode and the second electrode. The first electrodes are parts of stripe-shaped electrodes, which are arranged parallel to each other and which are isolated against each other. The memory cells are grouped into memory cell groups, each memory cell group defining a memory cell group area and being configured such that corresponding first electrodes are individually addressable via the stripe-shaped electrodes, and corresponding second electrodes are commonly addressable via a common select device arranged within the memory cell group area of the memory cell group. The method includes selecting a memory cell into which data has to be stored, selecting a memory cell group including the selected memory cell, and writing the data to be stored by applying a writing signal to the active material of the memory cell selected using the stripe-shaped electrode assigned to the selected memory cell and the selecting device assigned to the selected memory cell group as writing signal suppliers.

According to one embodiment of the present invention, a computer program is provided configured to perform, when being carried out on a computing device or a digital signal processor, a method of reading data stored within a memory device. The memory device includes a plurality of memory cells, each of which has a first electrode, a second electrode and an active material arranged between the first electrode and the second electrode. The first electrodes are parts of stripe-shaped electrodes, which are arranged parallel to each other and which are isolated against each other. The memory cells are grouped into memory cell groups, each memory cell group defining a memory cell group area and being configured such that corresponding first electrodes are individually addressable via the stripe-shaped electrodes, and corresponding second electrodes are commonly addressable via a common select device arranged within the memory cell group area of the memory cell group. The method includes selecting a memory cell from which data has to be read, selecting a memory cell group including the selected memory cell, and reading the data stored within the memory cell by applying a sensing signal to the selected memory cell via the stripe-shaped electrode assigned to the selected memory cell and the selecting device assigned to the selected memory cell group.

According to one embodiment of the present invention, a computer program is provided configured to perform, when being carried out on a computing device or a digital signal processor, a method of writing data into a memory device. The memory device includes a plurality of memory cells, each of which has a first electrode, a second electrode and an active material arranged between the first electrode and the second electrode. The first electrodes are parts of stripe-shaped electrodes, which are arranged parallel to each other and which are isolated against each other. The memory cells are grouped into memory cell groups, each memory cell group defining a memory cell group area and being configured such that corresponding first electrodes are individually addressable via the stripe-shaped electrodes, and corresponding second electrodes are commonly addressable via a common select device arranged within the memory cell group area of the memory cell group. The method includes selecting a memory cell into which data has to be stored, selecting a memory cell group including the selected memory cell, and writing the data to be stored by applying a writing signal to the active material of the memory cell selected using the stripe-shaped electrode assigned to the selected memory cell and the selecting device assigned to the selected memory cell group as writing signal suppliers.

According to one embodiment of the present invention, a data carrier configured to store computer program product as discussed above is provided.

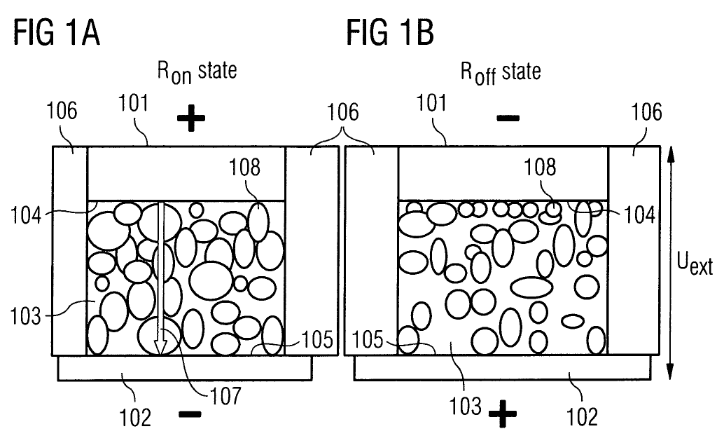

Since the embodiments of the present invention can be applied to resistive memory devices like solid electrolyte memory devices (also referred to as CBRAM (conductive bridging random access memory) devices), in the following description, making reference to FIGS. 1a and 1b, a basic principle underlying CBRAM devices will be explained.

As shown in FIG. 1a, a CBRAM cell includes a first electrode 101 a second electrode 102, and a solid electrolyte block (in the following also referred to as ion conductor block) 103 sandwiched between the first electrode 101 and the second electrode 102. The first electrode 101 contacts a first surface 104 of the ion conductor block 103, the second electrode 102 contacts a second surface 105 of the ion conductor block 103. The ion conductor block 103 is isolated against its environment by an isolation structure 106. The first surface 104 usually is the top surface, the second surface 105 the bottom surface of the ion conductor 103. In the same way, the first electrode 101 generally is the top electrode, and the second electrode 102 the bottom electrode of the CBRAM cell. One of the first electrode 101 and the second electrode 102 is a reactive electrode, the other one an inert electrode. Here, the first electrode 101 is the reactive electrode, and the second electrode 102 is the inert electrode. In this example, the first electrode 101 includes silver (Ag), the ion conductor block 103 includes silver-doped chalcogenide material, and the isolation structure 106 includes SiO₂.

If a voltage as indicated in FIG. 1a is applied across the ion conductor block 103, a redox reaction is initiated, which drives Ag⁺ ions out of the first electrode 101 into the ion conductor block 103 where they are reduced to Ag, thereby forming Ag rich clusters within the ion conductor block 103. If the voltage applied across the ion conductor block 103 is applied for a long period of time, the size and the number of Ag rich clusters within the ion conductor block 103 is increased to such an extent that a conductive bridge 107 between the first electrode 101 and the second electrode 102 is formed. In case that a voltage is applied across the ion conductor 103 as shown in FIG. 1b (inverse voltage compared to the voltage applied in FIG. 1a), a redox reaction is initiated that drives Ag⁺ ions out of the ion conductor block 103 into the first electrode 101 where they are reduced to Ag. As a consequence, the size and the number of Ag rich clusters within the ion conductor block 103 is reduced, thereby erasing the conductive bridge 107.

In order to determine the current memory status of a CBRAM cell, a sensing signal like a sensing current (or a sensing voltage) is applied to (routed through) the CBRAM cell. The sensing current experiences a high resistance in case no conductive bridge 107 exists within the CBRAM cell, and experiences a low resistance in case a conductive bridge 107 exists within the CBRAM cell. A high resistance may for example represent “0,” whereas a low resistance represents “1,” or vice versa.

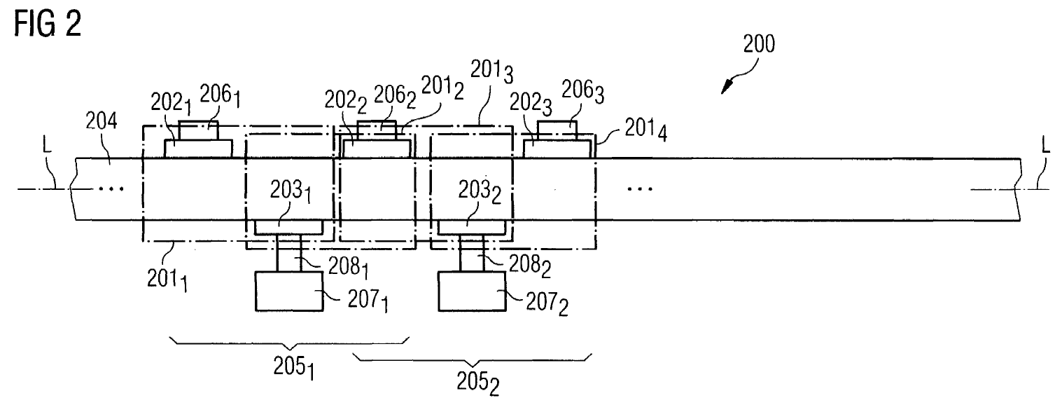

FIG. 2 shows an embodiment 200 of a memory device illustrating a principle of embodiments of memory devices according to the present invention. The embodiment 200 includes a plurality of memory cells 201, each memory cell 201 including a first electrode 202, a second electrode 203 and a part of an active material 204 layer arranged between the first electrode 202 and the second electrode 203. The plurality of memory cells 201 is divided into memory cell groups 205. Here, a first memory cell group 205₁ includes a first memory cell 201₁ and a second memory cell 201₂, and a second memory cell group 205₂ includes a third memory cell 201₃ and a fourth memory cell 201₄. The first memory cell 201₁ includes a first top electrode 202₁ and a first common bottom electrode 203₁. The second memory cell 201₂ includes the first common bottom electrode 203₁ and a second top electrode 202₂. The third memory cell 201₃ includes the second top electrode 202₂ and a second common bottom electrode 203₂. The fourth memory cell 201₄ includes the second common bottom electrode 203₂ and a third top electrode 202₃. Each of the first to fourth memory cells 201₁ to 201₄ includes a part of the active material 204 layer disposed between the respective top electrode 202 and the respective bottom electrode 203. The first memory cell group 205₁ overlaps with the second memory cell group 205₂, i.e., the second top electrode 202₂ is shared by the first memory cell group 205₁ and the second memory cell group 205₂. Each top electrode 202 of a memory cell group 205 is individually addressable via an address line 206. For example, the first top electrode 202₁ is individually addressable using a first address line 206₁, the second top electrode 202₂ is individually addressable by a second address line 206₂, and the third top electrode 2023 is individually addressable using a third address line 206₃. The first memory cell 201₁ and the second memory cell 201₂ of the first memory cell group 205₁ share a common bottom electrode 203, namely the first common bottom electrode 203₁. The first common bottom electrode 203₁ is addressable via a first common select device 207₁ being electrically connected to the first common bottom electrode 203₁ via a first electrical connection 208₁. The third memory cell 201₃ and the fourth memory cell 201₄ share a common bottom electrode 203, namely the second common bottom electrode 203₂. The second common bottom electrode 203₂ is electrically connected to a second common select device 207₂ via a second electrical connection 208₂.

In order to address, for example, the first memory cell 201₁, the first top electrode 202₁ and the first common bottom electrode 203₁ are selected using the first address line 206₁ and the first common select device 207₁. In order to address, for example, the second memory cell 201₂, the second top electrode 202₂ and the first common bottom electrode 203₁ are selected using the second address line 206₂ and the first common select device 207₁. In order to address the third memory cell 201₃, the second top electrode 202₂ and the second common bottom electrode 203₂ are selected using the second address line 206₂ and the second common select device 207₂. In order to address the fourth memory cell 201₄, the third top electrode 202₃ and the second common bottom electrode 203₂ are selected using the third address line 206₃ and the second common select device 207₂.

Since only one select device 207 is used for each memory cell group 205, the spatial dimensions of the select devices 207 are not limiting when scaling down the dimensions of the memory device. Thus, high memory densities can be achieved without scaling down the physical dimensions of the select devices 207.

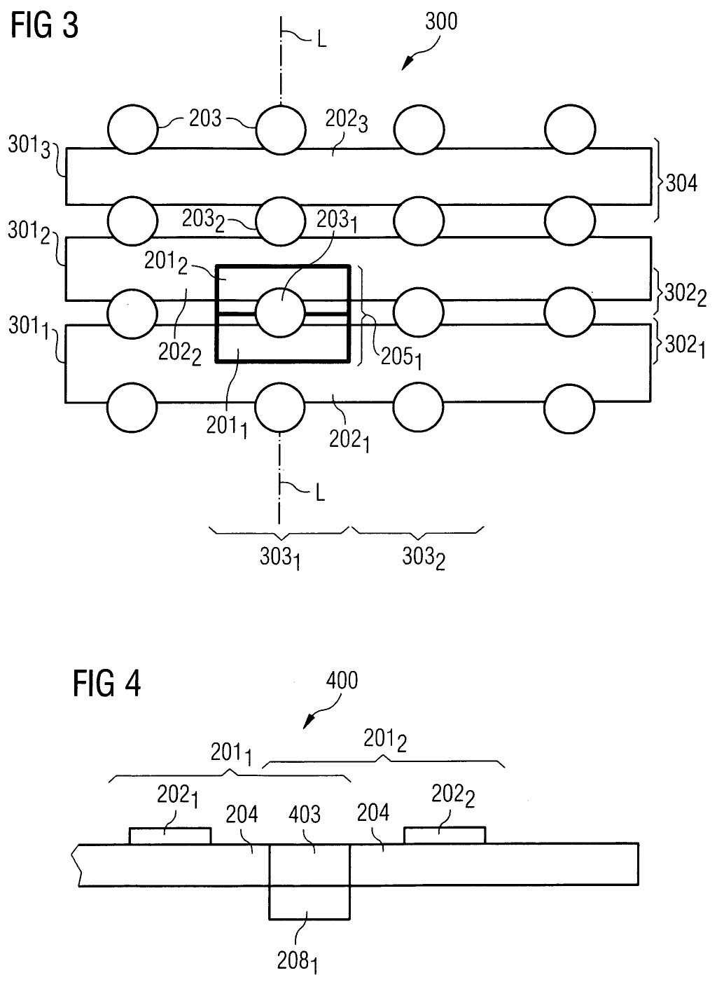

FIG. 3 shows an embodiment 300 of the memory device according to the present invention. The memory device 300 has an architecture being very similar to the architecture of the memory device 200 shown in FIG. 2 (embodiment 200 substantially represents a cross-section of embodiment 300 along line L). However, in this embodiment, the address lines 206 are replaced by stripe-shaped electrodes 301, which are arranged parallel to each other and which are isolated against each other. The first electrodes 202 are parts of the stripe-shaped electrodes 301. Thus, the stripe-shaped electrodes 301 can be used both as address lines and as first electrodes, which makes it unnecessary to provide separate address lines 206 like in the embodiment 200 shown in FIG. 2.

In this embodiment, each memory cell group 205 includes two memory cells (for sake of simplicity, only a first memory cell group 205₁ is shown in FIG. 3), the first memory cell group 205₁ including a first memory cell 201₁ and a second memory cell 201₂. Each stripe-shaped electrode 301 is electrically connected to only one memory cell 201 of a memory cell group 205. For example, a first stripe-shaped electrode 301₁ is electrically connected only to the first memory cell group 205₁.

The stripe-shaped electrodes 301 may, for example, be generated by patterning a continuous common electrode covering the active material 204.

In this embodiment, the memory cells 201 form a memory cell array including memory cell rows 302 and memory cell columns 303. For example, the first memory cell 201₁ of the first memory cell group 205₁ is part of a first memory cell row 302₁, and the second memory cell 201₂ of the first memory cell group 205₁ is part of a second memory cell row 302₂. The stripe-shaped electrodes 301 are arranged parallel to the memory cell rows 302.

According to one embodiment of the present invention, the pitch 304 of the stripe-shaped electrodes 301 is substantially the same as that of the second electrodes 203. In this way, the lithographic process used to generate the stripe-shaped electrodes 301 has the same lithographic dimensions as the lithographic process used to generate the second electrodes 203. In this way, the fabrication process of the memory device 300 is simplified.

According to one embodiment of the present invention, the common select devices 207 (which are arranged below the second electrodes 203 and are not shown in FIG. 3) form a select device array including select device rows and select device columns, wherein the select devices of a select device column are simultaneously addressable. In this embodiment, each stripe-shaped electrode 301 is arranged perpendicular to a column of common select devices 207 simultaneously addressable.

In this embodiment, only one memory cell group (first memory cell group 205₁) is denoted by reference signs. All other memory cell groups not being denoted by reference signs have the same structure as that of the first memory cell group 205₁. Thus, the memory device 300 can be interpreted as a concatenation of a plurality of identical memory cell groups 205.

In this embodiment, the first and second memory cell 201₁ and 201₂ of the first memory cell group 205₁ form as a whole an arrangement having a rectangular shape, the symmetry center of the arrangement being the first bottom electrode 203₁ (the common electrode (second electrode) of the first memory cell group 205₁). The same applies to the arrangement formed by the first and second stripe-shaped electrodes 302₁ and 302₂.

Thus, two different address lines, namely the first and the second stripe-shaped electrodes 301₁ and 301₂, are used (together with the first common bottom electrode 203₁ connected to a first common select device 207₁) to select the first and second memory cell 201₁ and 201₄.

The memory cell 300 shown in FIG. 3 may be a non-volatile and/or resistive memory device, for example, a solid electrolyte random access memory device. In this case, the active material 204 may, for example, comprise chalcogenide material (solid electrolyte material), the first electrodes 202 may comprise reactive material, and the second electrodes 203 may comprise inert material. A further example of a non-volatile memory device is a phase changing random access memory device (PCRAM). In this case, the active material is a phase changing material.

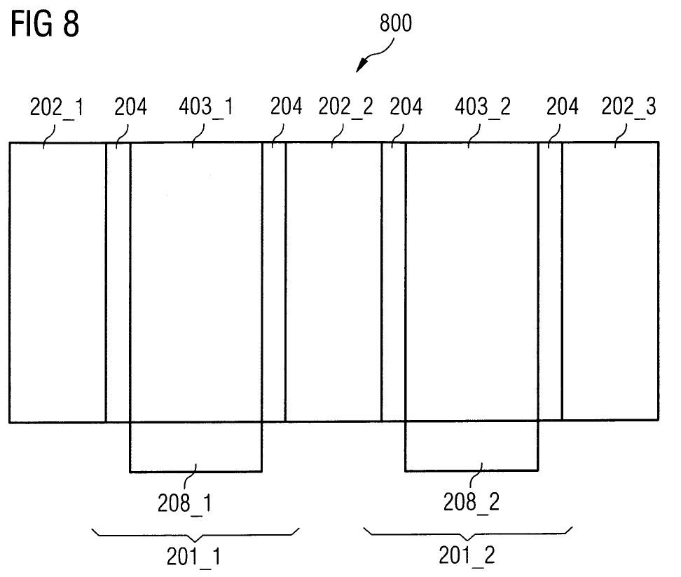

In an embodiment of the invention, a memory cell 800 shown in FIG. 8 may be a volatile memory cell, e.g., a dynamic random access memory cell (DRAM cell). The memory cell 800 may be understood as a deformed or distorted structure of the memory cell 400 of FIG. 4. In this case, capacities can be realized. In this embodiment of the invention, the active material of the memory cell 800 is a dielectric.

FIG. 4 shows an embodiment 400 of the memory device according to the present invention in which the memory cells 201 have a lateral architecture, whereas in the memory devices 200, 300, the memory cells 201 have a vertical architecture. “Lateral architecture” means that the first electrode 202, the active material 204 and the second electrode 203 of a memory cell 201 form a lateral structure (memory device 700), whereas “vertical architecture” means that the same components form a vertical structure. The lateral architecture results from the fact that the second electrodes 203 covering the bottom surface of the active material layer 204 have been replaced by electrodes 403 which are located not on, but within the active material layer 204. All embodiments of the memory device according to the present invention having a vertical architecture may also be applied in an analog manner to a memory device having a lateral architecture.

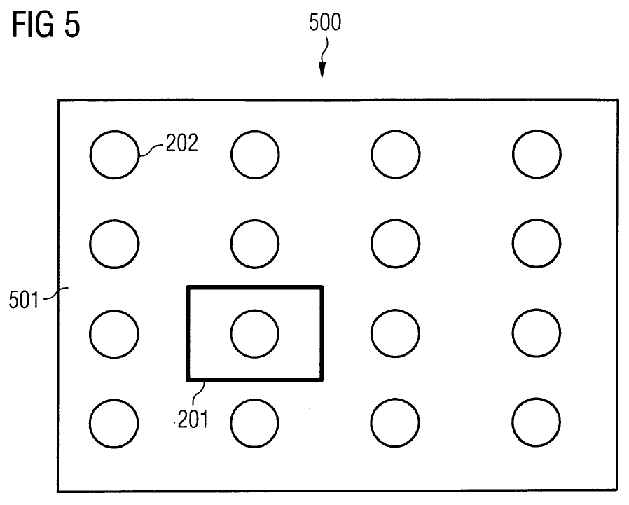

FIG. 5 shows a further embodiment 500 of a memory device in which a common electrode layer (usually the top electrode layer) 501 is used instead of a patterned electrode layer as shown in embodiments 200, 300 and 400. Compared to the embodiments 200, 300 and 400, the disadvantage of the embodiment 500 is that the memory density is halved since one select device 207 can only be used to address one, but not two memory cells 201.

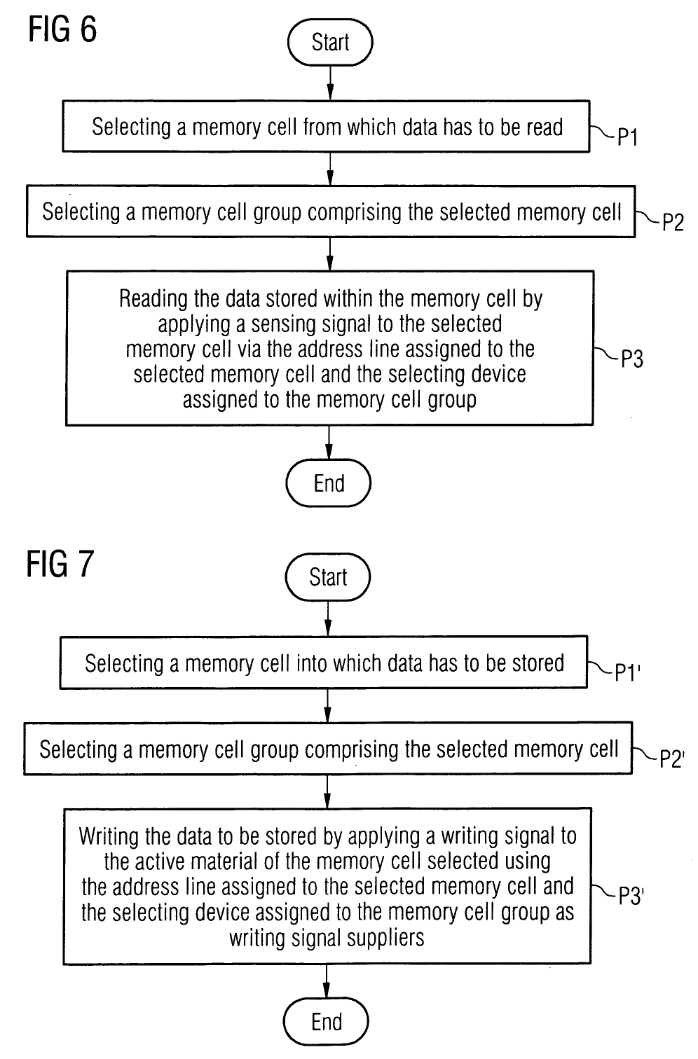

FIG. 6 shows one embodiment of the method of reading data from a memory cell of the memory device according to the present invention. In a first process P1, a memory cell is selected from which data has to be read. In a second process P2, a memory cell group comprising the selected memory cell is selected. In a third process P3, the data stored within the memory cell is read by routing a sensing current through (or by applying a sensing voltage to) the selected memory cell via the address line (e.g., a region of the first electrode to which the memory cell connects) assigned to the selected memory cell and the selecting device assigned to the memory cell group.

FIG. 7 shows one embodiment of the method of writing data into a memory cell of the memory device according to the present invention. In a first process P1′, a memory cell is selected from which data has to be read. In a second process P2′, a memory cell group comprising the selected memory cell is selected. In a third process P3′, the data to be stored is written by applying a writing voltage across the active material (or by applying a writing current through the active material) of the memory cell selected using the address line (e.g., a region of the first electrode to which the memory cell connects) assigned to the selected memory cell and the selecting device assigned to the memory cell group as writing voltage (writing current) suppliers.

In the following description, further aspects of exemplary embodiments of the present invention will be explained.

In many memory architectures, e.g., CBRAM, a storage element (CBRAM material stack) is used in conjunction with a select device (typically a transistor). The storage elements share a common electrode on one side and have separate selected electrodes on the other side resulting in one memory cell per select device (FIG. 5). According to one embodiment of the present invention, the common electrode is patterned into stripes serving two neighboring rows of contacts; at the same time, each row of contacts (to the select devices) serves two rows of the patterned electrode resulting in two selectable memory elements per select device (FIGS. 2, 3). Thus, the memory cell density is doubled in situations where the select device and not the active element are limiting the memory density.

According to one embodiment of the present invention, the pitch of the patterned top electrode is the same as that of the (contacts to the) select devices, for example, 2F to 4F in a typical 4F² to 8F² memory cell and thus inside the scope of technology node with no significant additional cost for patterning. According to one embodiment of the present invention, the direction of the stripe-shaped electrodes is orthogonal to lines of select devices addressed simultaneously. According to one embodiment of the present invention, small active elements <<F/2 are used. According to one embodiment of the present invention, CBRAM elements working at 15 nm are used. The embodiments of the present invention may be used in addition to known technologies, thus offering a factor two in memory density increase although no higher patterning densities are required.

The embodiments of the present invention can also be applied to other storage element types such as phase change random access memory (PCRAM), conductive bridging random access memory (CBRAM), magnetoresistive random access memory (MRAM), e.g., thermal select magnetoresistive random access memory (TS MRAM) or spin injection magnetoresistive random access memory (MRAM) or DRAM storage elements.

In the context of this description chalcogenide material (ion conductor) is to be understood, for example, as any compound containing sulphur, selenium, germanium and/or tellurium. In accordance with one embodiment of the invention, the ion conducting material is, for example, a compound, which is made of a chalcogenide and at least one metal of the group I or group II of the periodic system, for example, arsene-trisulfide-silver. Alternatively, the chalcogenide material contains germanium-sulfide (GeS), germanium-selenide (GeSe), tungsten oxide (WOₓ), copper sulfide (CuS) or the like. The ion conducting material may be a solid state electrolyte.

Furthermore, the ion conducting material can be made of a chalcogenide material containing metal ions, wherein the metal ions can be made of a metal, which is selected from a group consisting of silver, copper and zinc or of a combination or an alloy of these metals.

As used herein the terms “connected” and “coupled” are intended to include both direct and indirect connection and coupling, respectively.

The foregoing description has been presented for purposes of illustration and description. It is not intended to be exhaustive or to limit the invention to the precise form disclosed, and obviously many modifications and variations are possible in light of the disclosed teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined solely by the claims appended hereto.

What is claimed is:

1. A memory device comprising:
a plurality of memory cells, each memory cell comprising a first electrode, a second electrode and an active material arranged between the first electrode and the second electrode,
the first electrodes being arranged parallel to each other and being isolated from each other, and
the memory cells being grouped into memory cell groups, each memory cell group defining a memory cell group area and being configured such that corresponding first electrodes are individually addressable via the first electrodes, and corresponding second electrodes are commonly addressable via a common select device arranged within the memory cell group area of the memory cell group.

2. The memory device according to claim 1, wherein the first electrodes comprise parts of stripe-shaped electrodes.

3. The memory device according to claim 2, wherein the stripe-shaped electrodes are generated by patterning a continuous common electrode covering the active material.

4. The memory device according to claim 2, wherein the stripe-shaped electrodes comprise address lines.

5. The memory device according to claim 2, wherein the memory cells form a memory cell array comprising memory cell rows and memory cell columns, the stripe-shaped electrodes being arranged parallel to the memory cell rows.

6. The memory device according to claim 5, wherein the common select devices form a select device array comprising select device rows and select device columns, the select devices of a select device column being addressable simultaneously.

7. The memory device according to claim 6, wherein each stripe-shaped electrode is arranged perpendicular to a column of common select devices addressable simultaneously.

8. The memory device according to claim 2, wherein each memory cell group comprises two memory cells and wherein each stripe-shaped electrode is electrically connected to only one memory cell of a memory cell group.

9. The memory device according to claim 1, wherein the patterned first electrodes have a pitch that is substantially the same as that of the second electrodes.

10. The memory device according to claim 1, wherein the memory cells of a memory cell group comprise only one common second electrode, respectively.

11. The memory device according to claim 10, wherein each memory cell group is configured such that corresponding first electrodes are arranged around a common second electrode.

12. The memory device according to claim 1, wherein each memory cell group is configured such that corresponding first electrodes are arranged around a common second electrode in a point-symmetrical manner.

13. The memory device according to claim 1, wherein all memory cell groups have the same memory cell group architecture.

14. The memory device according to claim 1, wherein the memory cells have a vertical architecture.

15. The memory device according to claim 1, wherein the memory cells have a lateral architecture.

16. The memory device according to claim 1, wherein the memory device comprises a non-volatile memory device.

17. The memory device according to claim 16, wherein the memory device comprises a solid electrolyte random access memory device, the active material being solid electrolyte material.

18. The memory device according to claim 16, wherein the memory device comprises a phase changing random access memory device, the active material being phase changing material.

19. The memory device according to claim 1, wherein the first electrodes comprise top electrodes, and the second electrodes comprise bottom electrodes.

20. A dynamic random access memory (DRAM) device comprising:
a plurality of memory cells, each memory cell comprising a first electrode, a second electrode and a dielectric material arranged between the first electrode and the second electrode,
the first electrodes being parts of stripe-shaped electrodes that are arranged parallel to each other and that are isolated from each other, and
the memory cells being grouped into memory cell groups, each memory cell group defining a memory cell group area and being configured such that corresponding first electrodes are individually addressable via the stripe-shaped electrodes, and corresponding second electrodes are commonly addressable via a common select device arranged within the memory cell group area of the memory cell group.

21. A method of reading data stored within a memory device comprising a plurality of memory cells, each memory cell comprising a first electrode, a second electrode and an active material arranged between the first electrode and the second electrode, the first electrodes being parts of stripe-shaped electrodes that are arranged parallel to each other and that are isolated from each other, and the memory cells being grouped into memory cell groups, each memory cell group defining a memory cell group area and being configured such that corresponding first electrodes are individually addressable via the stripe-shaped electrodes, and corresponding second electrodes are commonly addressable via a common select device arranged within the memory cell group area of the memory cell group, the method comprising:
selecting a memory cell from which data has to be read;
selecting a memory cell group comprising the selected memory cell; and
reading data stored within the memory cell by applying a sensing signal to the selected memory cell via the stripe-shaped electrode assigned to the selected memory cell and the common select device assigned to the selected memory cell group.

22. A method of writing data into memory device comprising a plurality of memory cells, each memory cell comprising a first electrode, a second electrode and an active material arranged between the first electrode and the second electrode, the first electrodes being parts of stripe-shaped electrodes that are arranged parallel to each other and that are isolated against each other, and the memory cells being grouped into memory cell groups, each memory cell group defining a memory cell group area and being configured such that corresponding first electrodes are individually addressable via the stripe-shaped electrodes, and corresponding second electrodes are commonly addressable via a common select device arranged within the memory cell group area of the memory cell group, the method comprising:
selecting a memory cell into which data has to be stored;
selecting a memory cell group comprising the selected memory cell; and
writing the data to be stored by applying a writing signal to the active material of the memory cell selected using the stripe-shaped electrode assigned to the selected memory cell and the common select device assigned to the selected memory cell group as writing signal suppliers.

23. A computer program adapted to perform, when being carried out on a computing device or a digital signal processor, a method of reading data stored within a memory device comprising a plurality of memory cells, each of which comprising a first electrode, a second electrode and an active material arranged between the first electrode and the second electrode, the first electrodes being parts of stripe-shaped electrodes that are arranged parallel to each other and that are isolated from each other, and the memory cells being grouped into memory cell groups, each memory cell group defining a memory cell group area and being configured such that corresponding first electrodes are individually addressable via the stripe-shaped electrodes, and corresponding second electrodes are commonly addressable via a common select device arranged within the memory cell group area of the memory cell group, the method comprising:
selecting a memory cell from which data has to be read;
selecting a memory cell group comprising the selected memory cell; and
reading the data stored within the memory cell by applying a sensing signal to the selected memory cell via the stripe-shaped electrode assigned to the selected memory cell and the common select device assigned to the selected memory cell group.

24. A data carrier adapted to store a computer program according to claim 23.

25. A computer program adapted to perform, when being carried out on a computing device or a digital signal processor, a method of writing data into memory device comprising a plurality of memory cells, each of which comprising a first electrode, a second electrode and an active material arranged between the first electrode and the second electrode, the first electrodes being parts of stripe-shaped electrodes that are arranged parallel to each other and that are isolated against each other, and the memory cells being grouped into memory cell groups, each memory cell group defining a memory cell group area and being configured such that corresponding first electrodes are individually addressable via the stripe-shaped electrodes, and corresponding second electrodes are commonly addressable via a common select device arranged within the memory cell group area of the memory cell group, the method comprising:
selecting a memory cell into which data has to be stored;
selecting a memory cell group comprising the selected memory cell;
writing the data to be stored by applying a writing signal to the active material of the memory cell selected using the stripe-shaped electrode assigned to the selected memory cell and the common select device assigned to the selected memory cell group as writing signal suppliers.

26. A data carrier adapted to store a computer program according to claim 25.
